(19) United States
(12) Patent Application Publication
(10) Pub. No.: US 2009/0102543 A1
(43) Pub. Date: Apr. 23, 2009

(54) NEGATIVE VOLTAGE GENERATING CIRCUIT

(75) Inventor: Jin-Liang Xiong, Shenzhen (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 11/957,501

(22) Filed: Dec. 17, 2007

(30) Foreign Application Priority Data
Oct. 17, 2007 (CN) 200710202109.3

(51) Int. Cl. G11C 5/14

(52) U.S. Cl. 327/530

(57) ABSTRACT

A negative voltage generating circuit for providing a negative voltage for an electronic circuit, includes a voltage input terminal receiving a positive voltage, a voltage output terminal outputting the negative voltage to the electronic circuit, a pulse generator, a first transistor, a second transistor, a first capacitor, at least one first diode, a second diode, a second capacitor, and a first resistor. When the pulse generator outputs a high level signal, the capacitor is charged, and the full voltage of the capacitor equals the difference between the voltage of the voltage input terminal and the voltage of the at least one first diode. When the pulse generator outputs a low level signal, the capacitor discharges through the first resistor, the voltage output terminal outputs a negative voltage, the value of the negative voltage equals the difference between the voltage of the capacitor and the voltage of the second diode.

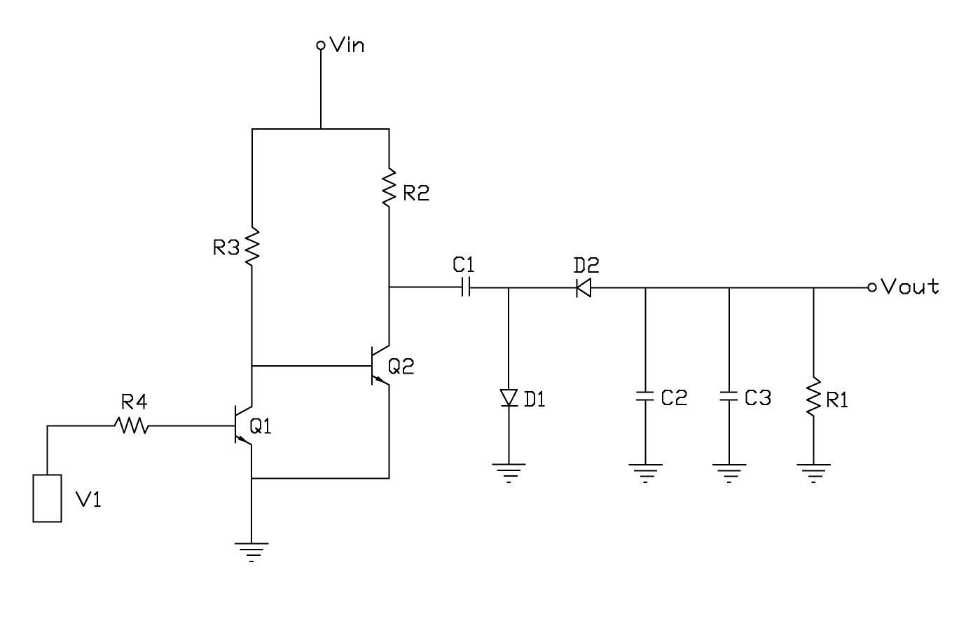

### BACKGROUND

1. Field of the Invention

The present invention relates to a negative voltage generating circuit.

2. Description of Related Art

With rapid development of electronic technology, more and more electronic systems need both positive and negative voltages to operate, for example, operational amplifiers and computer PCI (Peripheral Component Interconnect) cards require negative voltage to operate.

What is desired, therefore, is to provide a simple low-cost negative voltage generating circuit for providing a negative voltage output.

### SUMMARY

In one embodiment, a negative voltage generating circuit for providing a negative voltage to an electronic circuit, includes a voltage input terminal receiving a positive voltage, a voltage output terminal outputting negative voltage to the electronic circuit, a pulse generator alternately outputting a high level signal and a low level signal, a first transistor, a second transistor, a first capacitor, at least one first diode, a second diode, a second capacitor, and a first resistor. The base of the first transistor is connected to the pulse generator. The collector of the first transistor is connected to the voltage input terminal. The emitter of the first transistor is grounded. The base of the second transistor is connected to the collector of the first transistor. The emitter of the second transistor is grounded. The collector of the second transistor is connected to the voltage input terminal. The positive terminal of the first capacitor is connected to the collector of the second transistor. The negative terminal of the first capacitor is connected to the voltage output terminal. The anode of the at least one first diode is connected to the negative terminal of the first capacitor. The cathode of the at least one first diode is grounded. The anode of the second diode is connected to the voltage output terminal. The cathode of the second diode is connected to the negative terminal of the first capacitor. The second capacitor is connected between the anode of the second diode and ground. The first resistor is connected between the anode of the second diode and ground.

Other advantages and novel features of the present invention will become more apparent from the following detailed description of preferred embodiment when taken in conjunction with the accompanying drawing, in which:

### BRIEF DESCRIPTION OF THE DRAWINGS

The drawing is a circuit diagram of a negative voltage generating circuit in accordance with an embodiment of the present invention.

### DETAILED DESCRIPTION

Referring to the drawing, a negative voltage generating circuit for providing a negative voltage for an electronic circuit in accordance with an embodiment of the present invention includes a voltage input terminal Vin receiving a positive voltage, a voltage output terminal Vout outputting the negative voltage to the electronic circuit, a pulse generator V1 alternately outputting a high level signal and a low level signal, four resistors R1˜R4, two transistors Q1˜Q2, three capacitors C1˜C3, and two diodes D1˜D2.

The voltage input terminal Vin is connected to the collector of the transistor Q1 via the resistor R3, and connected to the collector of the transistor Q2 via the resistor R2. The collector of the transistor Q1 is connected to the base of the transistor Q2. The base of the transistor Q1 is connected to the pulse generator V1 via the resistor R4. The emitter of the transistor Q1 is connected to the emitter of the transistor Q2 and ground. The collector of the transistor Q2 is connected to the positive terminal of the capacitor C1. The negative terminal of the capacitor C1 is connected to the anode of the diode D1 and the cathode of the diode D2. The cathode of the diode D1 is grounded. The anode of the diode D2 is connected to the voltage output terminal Vout. The voltage output terminal Vout is grounded via the resistor R1, the capacitor C2, and the capacitor C3 connected in parallel.

In this embodiment, the capacitor C1 is an electrolytic capacitor. The diode D1 is a Schottky diode. The pulse generator V1 is a 555 timer.

In use, the pulse generator V1 outputs a square wave pulse signal. When the pulse generator V1 outputs a high level signal, the transistor Q1 is turned on, and the collector of the transistor Q1 outputs a low level signal, the transistor Q2 is turned off, and the voltage input terminal Vin charges the capacitor C1. When the capacitor C1 is fully charged, no current passes through the resistor R2, the diode D1 has a voltage drop (such as 0.2 V), thereby, the full voltage of the capacitor C1 equals the difference between the voltage of the voltage input terminal Vin and the voltage of the diode D1.

When the pulse generator V1 outputs a low level signal, the transistor Q1 is turned off, the collector of the transistor Q1 outputs a high level signal, the transistor Q2 is turned on, the collector of the transistor Q2 outputs a low level signal, therefore, the voltage of the positive terminal of the capacitor C1 is 0V, and a voltage of the negative terminal of the capacitor C1 is negative. So the capacitor C1 discharges through the resistor R1, and the voltage output terminal Vout outputs a negative working voltage to the electronic circuit.

When the pulse generator V1 outputs high level and low level signals alternately, the capacitor C1 charges and discharges continuously. When the pulse generator V1 outputs a low level signal, the capacitor C1 discharges through the resistor R1, at the same time, the capacitors C2 and C3 are charged. When the pulse generator V1 outputs a high level signal, the capacitor C1 is charged, at the same time, the capacitors C2 and C3 discharge through the resistor R1, the voltage output terminal Vout stably and continuously outputs a negative voltage.

For example, the voltage input terminal Vin receives a voltage, when the pulse generator V1 outputs a high level signal, the capacitor C1 is charged, and the full voltage of the capacitor C1 equals the difference between the voltage of the voltage input terminal Vin and the voltage of the diode D1. When the pulse generator V1 outputs a low level signal, a voltage of the positive terminal of the capacitor C1 is 0V, and a voltage of the negative terminal of the capacitor C1 is negative, the capacitor C1 discharges through the resistor R1, the voltage output terminal Vout outputs a negative voltage, the value of the negative voltage equals the difference between the voltage of the capacitor C1 and the voltage of the diode D2.

Because the negative voltage generating circuit can comprise one or more diodes connected between the negative terminal of the capacitor C1 and ground, which essentially forms a voltage dividing circuit, therefore voltage output at the terminal Vout can be selected according to the value and number of diodes used therein. The negative voltage generating circuit is simple, and low-cost.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A negative voltage generating circuit for providing a negative voltage for an electronic circuit, comprising:
a voltage input terminal receiving a positive voltage;
a voltage output terminal outputting the negative voltage to the electronic circuit;
a pulse generator alternately outputting a high level signal and a low level signal;
a first transistor, the base of the first transistor connected to the pulse generator, the collector of the first transistor connected to the voltage input terminal, the emitter of the first transistor grounded;
a second transistor, the base of the second transistor connected to the collector of the first transistor, the emitter of the second transistor grounded, the collector of the second transistor connected to the voltage input terminal;
a first capacitor, the positive terminal of the first capacitor connected to the collector of the second transistor;
at least one first diode, the anode of the at least one first diode connected to the negative terminal of the first capacitor, the cathode of the at least one first diode grounded;
a second diode, the anode of the second diode connected to the voltage output terminal, the cathode of the second diode connected to the negative terminal of the first capacitor;
a second capacitor connected between the anode of the second diode and ground; and
a first resistor connected between the anode of the second diode and ground.

2. The negative voltage generating circuit as claimed in claim 1, further comprising:
a second resistor connected between the voltage input terminal and the collector of the second transistor; and a third resistor connected between the voltage input terminal and the collector of the first transistor.

3. The negative voltage generating circuit as claimed in claim 1, further comprising:
a fourth resistor connected between the base of the first transistor and the pulse generator.

4. The negative voltage generating circuit as claimed in claim 1, further comprising:
a third capacitor connected between the anode of the second diode and ground.

5. The negative voltage generating circuit as claimed in claim 1, wherein the first capacitor is an electrolytic capacitor.

6. The negative voltage generating circuit as claimed in claim 1, wherein the first diode is a Schottky diode.

7. The negative voltage generating circuit as claimed in claim 1, wherein the pulse generator is a 555 timer.
